(19) United States
(12) Patent Application Publication
(10) Pub. No.: US 2014/0007918 A1
(43) Pub. Date: Jan. 9, 2014

(54) PHOTOVOLTAIC DEVICE

(71) Applicant: AU OPTRONICS CORPORATION, Hsin-Chu (TW)

(72) Inventors: Wei-Jieh LEE, HSIN-CHU (TW); Kuan-Wen TUNG, HSIN-CHU (TW); Chun-Ming YANG, HSIN-CHU (TW); Huang-Chi TSENG, HSIN-CHU (TW); Chiuan-Ting LI, HSIN-CHU (TW); Wei-Sheng SU, HSIN-CHU (TW); Yen-Cheng HU, HSIN-CHU (TW)

(73) Assignee: AU OPTRONICS CORPORATION, HSIN-CHU (TW)

(21) Appl. No.: 13/773,742

(22) Filed: Feb. 22, 2013

(30) Foreign Application Priority Data
Jul. 9, 2012 (CN) 201210236408.X

(51) Int. Cl. H01L 31/052

(52) U.S. Cl. CPC H01L 31/0527
USPC 136/246

(57) ABSTRACT

A photovoltaic device provided in the present disclosure includes a superstrate, a lower substrate, a plurality of photovoltaic cells and a package structure. The superstrate is light-transmissive, and arranged in parallel with the substrate. The photovoltaic cells are disposed side-by-side at intervals with each other between the superstrate and the substrate, and a gap zone is defined by two facing lateral surfaces of every two of the neighboring photovoltaic cells. The package structure is sandwiched between the superstrate and the substrate, and encapsulates the photovoltaic cells between the superstrate and the substrate in which a reflection portion is provided in the package structure, and located in the gap zone for reflecting lights from the superstrate back to the photovoltaic cells.

### RELATED APPLICATIONS

This application claims priority to China Application Serial Number 201210236408.X, filed Jul. 9, 2012, which is herein incorporated by reference.

### BACKGROUND

1. Technical Field

The present disclosure relates to a photovoltaic device, and more particularly to a photovoltaic device having a reflection portion.

2. Description of Related Art

Normally, a photovoltaic device is mostly installed outdoors for effectively receiving sunlight, so as to convert the sunlight into electric power.

FIG. 1 illustrates a sectional view of a conventional photovoltaic device under an operation state. The photovoltaic device 10 includes a superstrate 20, a substrate 30, a plurality of photovoltaic cells 50 and a package structure 40. The package structure 40 is sandwiched between the superstrate 20 and the substrate 30, and the photovoltaic cells 50 are encapsulated in the package structure 40. Therefore, when sunlight L1 penetrates through the superstrate 20 and arrives at a light-receiving surface 51 of one of the photovoltaic cells 50, the photovoltaic cells 50 can effectively convert the sunlight L1 into electric power.

However, since the photovoltaic cells 50 are arranged at intervals in the package structure 40, a gap zone G is defined by every two neighboring photovoltaic cells 50. When sunlight L2 exactly passes through one of the gap zones G but fails to be reflected back to one of the light-receiving surfaces 51 thereof, the sunlight L2 cannot be used for converting into electric power by the photovoltaic cell 50. In this regard, the photovoltaic device 10 lacks an effective solution in improving the conversion efficiency of photovoltaic device.

Given the above, the conventional photovoltaic device still has the shortages of insufficiently improving the conversion efficiency of photovoltaic device, and requires further improvements in conversion efficiency. How to effectively solve the above-mentioned shortages has become one of the most urgent issue for the photovoltaic device.

### SUMMARY

One aspect of the present disclosure is to provide a photovoltaic device which enables lights to be reflected in advance before the lights go through the gap between the photovoltaic cells, thus, the possibilities that the lights are invalided for converting into electric power can be decreased, and accordingly, the total conversion efficiency of the photovoltaic device can be further increased.

Another aspect of the present disclosure is to provide a photovoltaic device which increases the utilization of different directions of the incident angles of lights.

Thus, the photovoltaic device provided by one practice of the present disclosure includes a superstrate, a substrate, a plurality of photovoltaic cells and a package structure. The superstrate is light-transmissive, and the substrate is arranged in parallel with the superstrate, and the photovoltaic cells are disposed side-by-side at intervals with each other between the superstrate and the substrate, in which a gap zone is defined by two facing lateral surfaces of every two of the neighboring photovoltaic cells. The package structure is sandwiched between the superstrate and the substrate, and encapsulates the photovoltaic cells between the superstrate and the substrate. Moreover, a reflection portion is provided in the package structure, and the reflection is located in the gap zone for reflecting lights from the superstrate back to the photovoltaic cells.

According to a first embodiment thereof, the package structure includes a first package layer and a second package layer. The first package layer is light-transmissive, and entirely contacted with one surface of the superstrate. The second package layer is light-reflective, and is stacked on one surface of the first package layer opposite to the superstrate and entirely contacted with one surface of the substrate. The photovoltaic cells are encapsulated and sandwiched between the first package layer and the second package layer. The reflection portion is a surface of the second package layer in contact to the first package layer in the gap zone.

According to a second embodiment thereof, the package structure includes a first package layer and a second package layer. The first package layer is light-transmissive, and entirely contacted with one surface of the superstrate. The second package layer includes a plurality of first portions and a plurality of second portions. Each of the first portions has a top surface thereof with the same area as a bottom surface of one of the photovoltaic cells, and is sandwiched between one of the photovoltaic cell and the substrate. The second portions are light-reflective, respectively arranged at intervals with each other, and respectively disposed in the gap zones. One surface of each of the second portions is contacted with the first package layer, and the other surface thereof is contacted with the substrate. The photovoltaic cells are encapsulated and sandwiched between the first package layer and the first portions, and the reflection portion is a surface of one of the second portions contacting to the first package layer in the gap zone.

According to a third embodiment thereof, the package structure includes a first package layer and a second package layer. The first package layer is light-transmissive, and entirely contacted with one surface of the superstrate. The second package layer is light-transmissive, and entirely contacted with one surface of the substrate. The photovoltaic cells are encapsulated and sandwiched between the first package layer and the second package layer. The reflection portion comprises a plurality of reflective films. The reflective films are light-reflective, and sandwiched between the first package layer and the second package layer. Each of the reflective films is located in one of the gap zones, and connected with the lateral surfaces of the neighboring photovoltaic cells. Each reflective film is sandwiched between the first package layer and the second package layer.

According to a fourth embodiment thereof, the package structure comprises a first package layer. The first package layer is light-transmissive, and sandwiched between the superstrate and substrate. The reflection portion comprises a plurality of reflective particles. The reflective particles are light-reflective, and are distributed in the first package layer corresponding to the gap zones.

According to a fifth embodiment thereof, the package structure includes a first package layer and a second package layer. The first package layer is light-transmissive, and entirely contacted with one surface of the superstrate. The second package layer is light-transmissive, and entirely contacted with one surface of the substrate. The photovoltaic cells are encapsulated and sandwiched between the first package layer and the second package layer. The reflection portion comprises a plurality of filling layers. The filling layers are light-reflective, and sandwiched between the first package layer and the second package layer, wherein each of the filling layers is located in one of the gap zones, and connected with the lateral surfaces of the neighboring photovoltaic cells.

In one alternative of the fifth embodiment, each of the filling layers is completely filled in one of the gap zones.

In the aforementioned embodiments thereof, a light-reflection rate of the reflection portion is in a range of 90%-100%, and greater than a light-reflection rate of the first package layer.

In the aforementioned embodiments thereof, the substrate is light-blocked or light-transmissive.

In the aforementioned embodiments thereof, the substrate is light-transmissive, and the reflection portion is light-transflective, and has a light-reflection rate in a range of 50%-90%, and greater than a light-reflection rate of the first package layer.

The photovoltaic device provided by another practice of the present disclosure includes a superstrate, a substrate, a plurality of photovoltaic cells and a package structure. The superstrate is light-transmissive, and the substrate is arranged in parallel with the superstrate, and the photovoltaic cells are disposed flat and arranged at intervals between the superstrate and the substrate in which a gap zone is defined between two lateral surfaces of each two neighboring photovoltaic cells facing to each other. The package structure is sandwiched between the superstrate and the substrate, and encapsulates the photovoltaic cells therein. The package structure includes a first package layer and a reflection portion. The first package layer is light-transmissive, and entirely contacted with one surface of the superstrate. The reflection portion is disposed in the gap zone for reflecting incident lights from the superstrate, in which a light-reflection rate of the reflection portion is greater than a light-reflection rate of the first package layer.

To sum up, with the reflection portion installed in the photovoltaic device, the incident lights of the photovoltaic device can be reflected in advance by the reflection portion, thus, the possibilities that the incident lights are invalided for converting into electric power can be decreased so as to further increase the total conversion efficiency of the photovoltaic device.

### BRIEF DESCRIPTION OF THE DRAWINGS

The present disclosure will be apparent to those skilled in the art by reading the following detailed description of a preferred embodiment thereof, with reference to the attached drawings, in which:

FIG. 1 is a sectional view of a conventional photovoltaic device under an operation state;

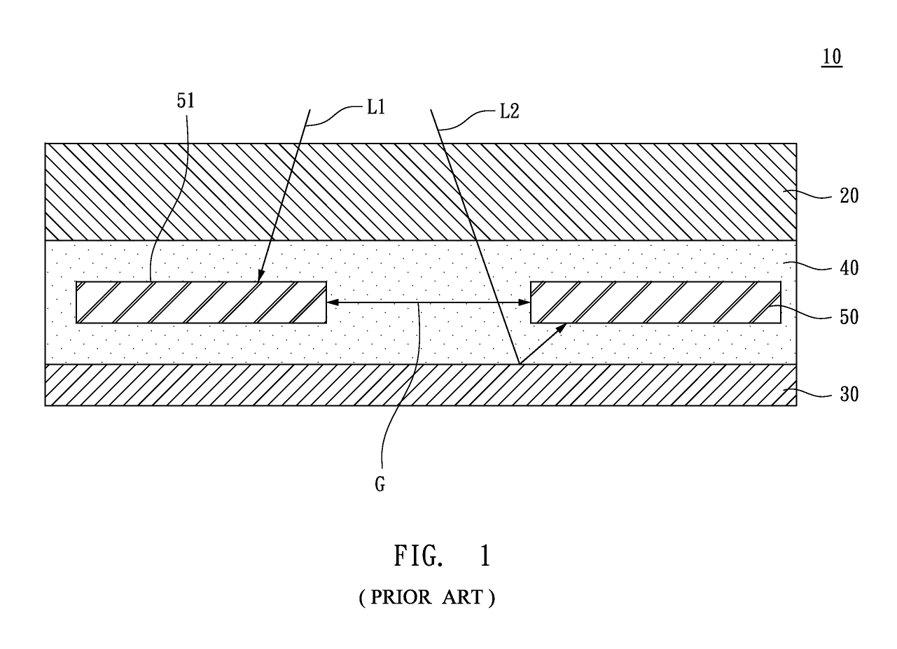

FIG. 2 is a top view of a photovoltaic device of the present disclosure;

FIG. 3A is a cross sectional view of FIG. 2 taken along A-A according to a first embodiment of the photovoltaic device of the present disclosure;

FIG. 3B is a cross sectional view of FIG. 2 taken along A-A according to a second embodiment of the photovoltaic device of the present disclosure;

FIG. 3C is a cross sectional view of FIG. 2 taken along A-A according to a alternative of a third embodiment of the photovoltaic device of the present disclosure;

FIG. 3D is a cross sectional view of FIG. 2 taken along A-A according to another alternative of the third embodiment of the photovoltaic device of the present disclosure;

FIG. 3E is a cross sectional view of FIG. 2 taken along A-A according to a alternative of a fourth embodiment of the photovoltaic device of the present disclosure;

FIG. 3F is a cross sectional view of FIG. 2 taken along A-A according to another alternative of the fourth embodiment of the photovoltaic device of the present disclosure;

FIG. 3G is a cross sectional view of FIG. 2 taken along A-A according to an alternative of a fifth embodiment of the photovoltaic device of the present disclosure;

FIG. 3H is a cross sectional view of FIG. 2 taken along A-A according to another alternative of the fifth embodiment of the photovoltaic device of the present disclosure;

FIG. 4A is a cross sectional view of FIG. 2 taken along A-A according to an alternative of the sixth embodiment of the photovoltaic device of the present disclosure;

FIG. 4B is a cross sectional view of FIG. 2 taken along A-A according to another alternative of the sixth embodiment of the photovoltaic device of the present disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

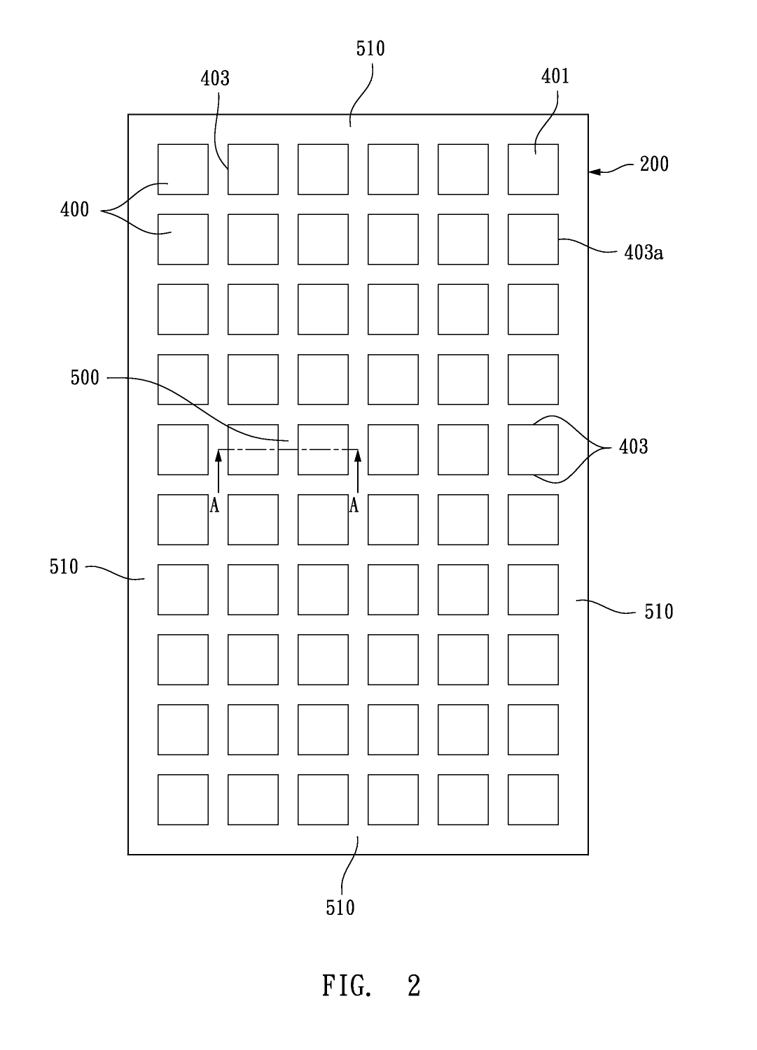

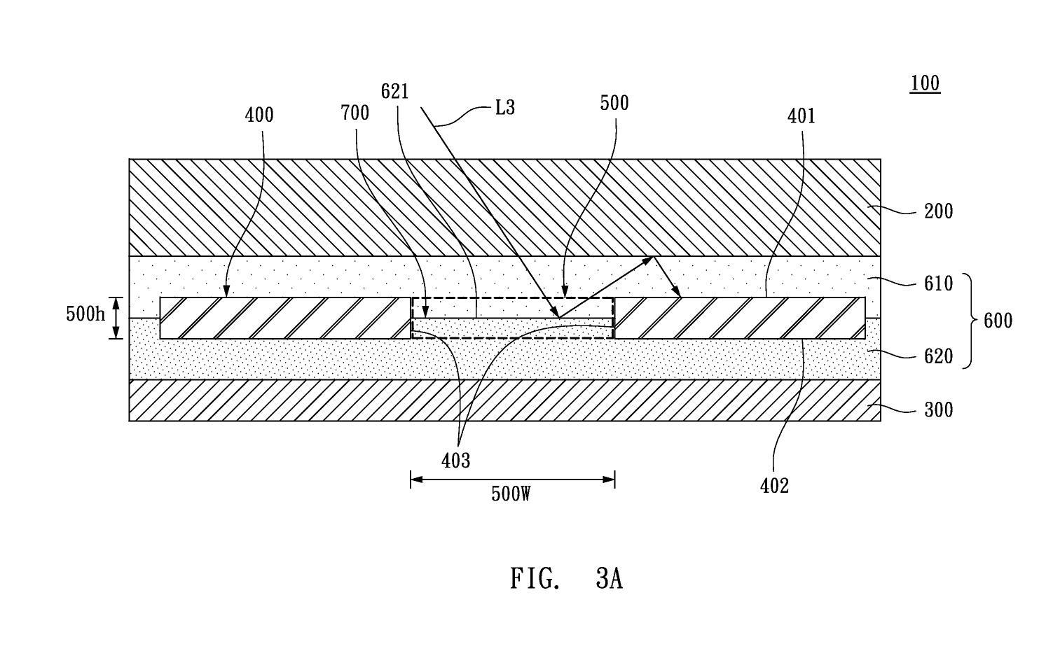

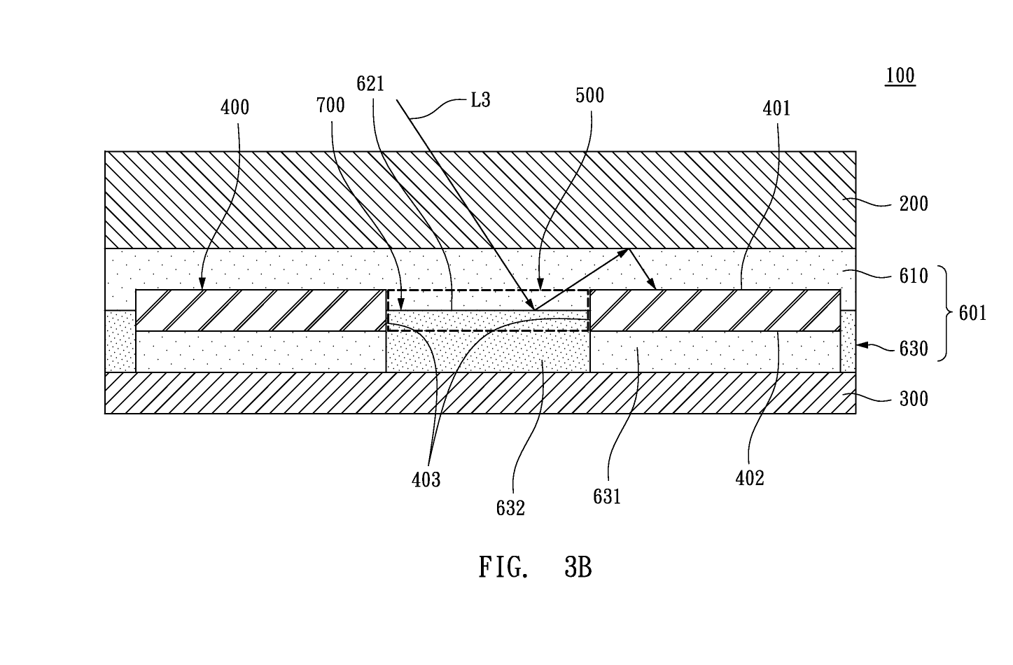

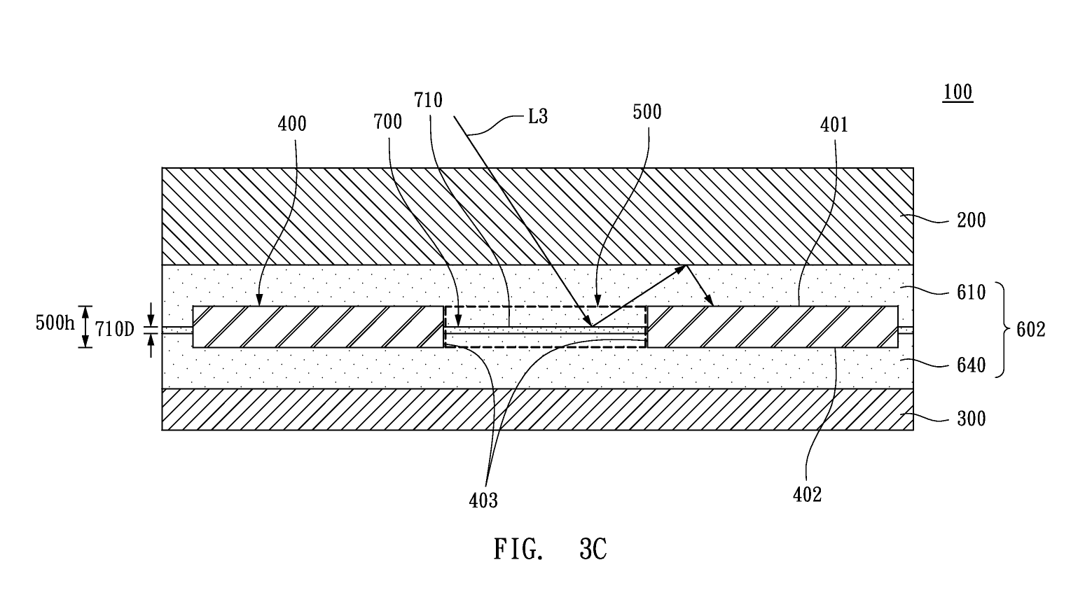

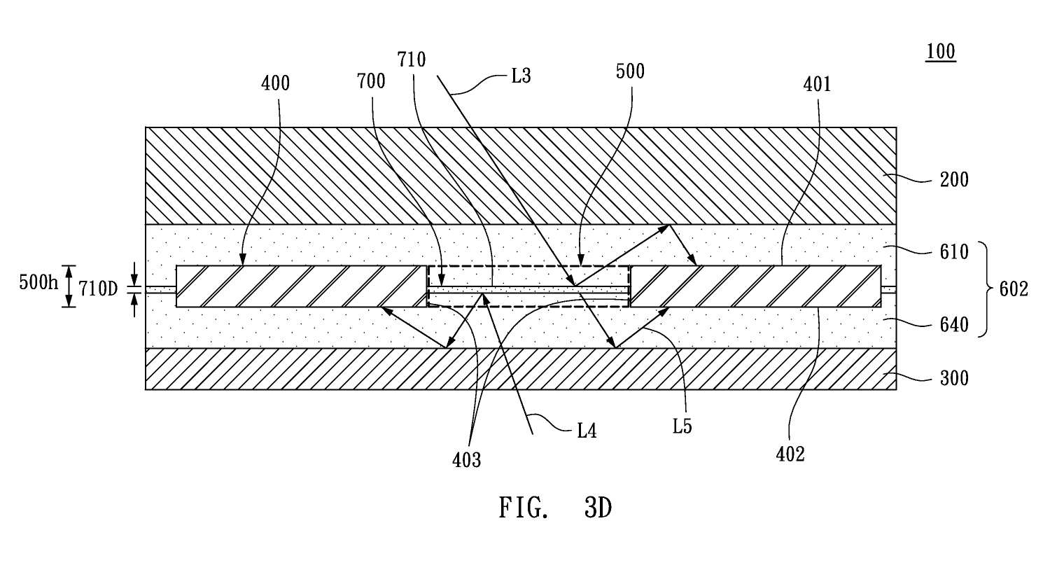

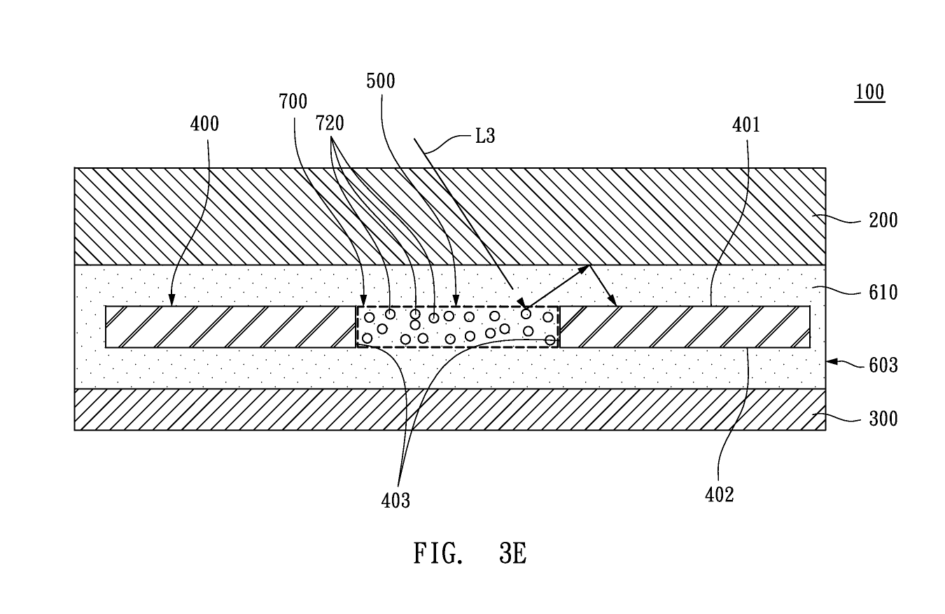

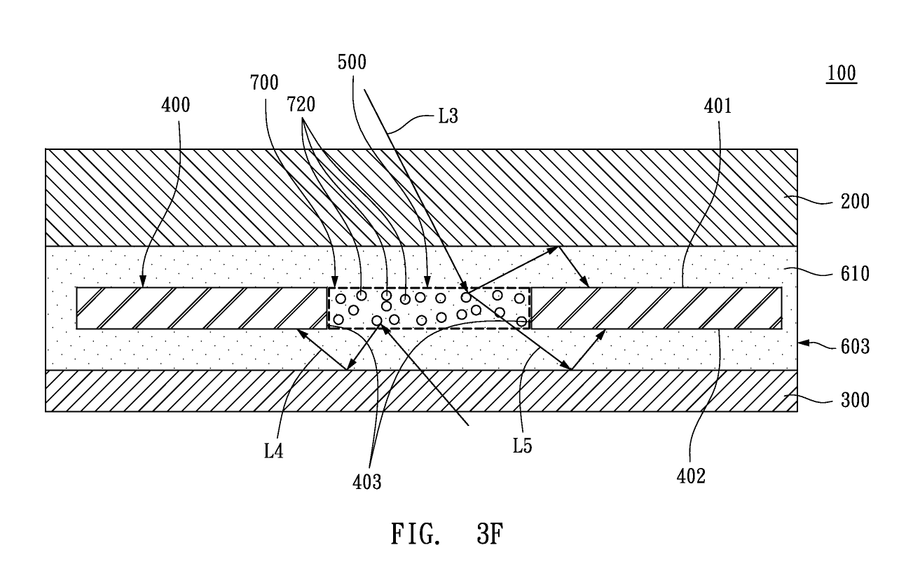

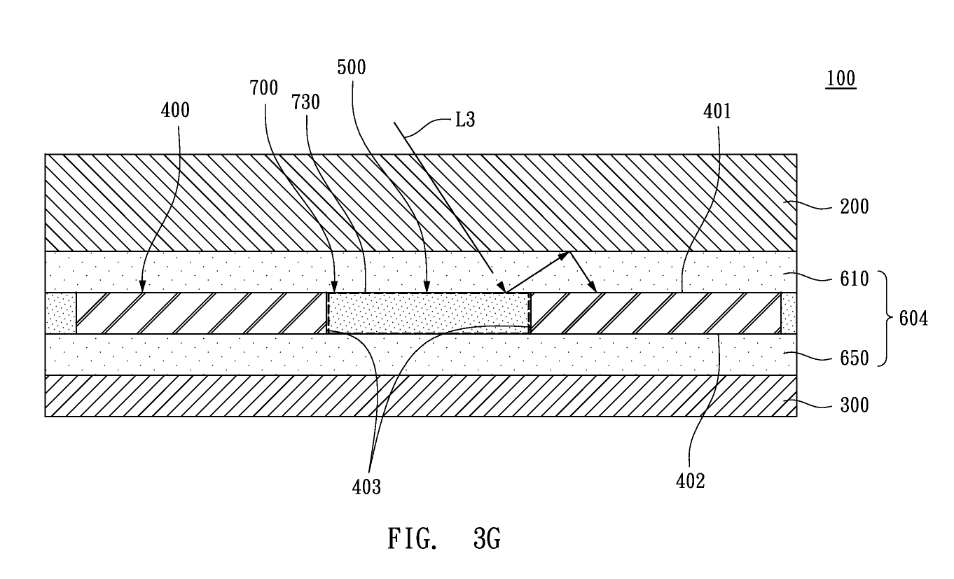

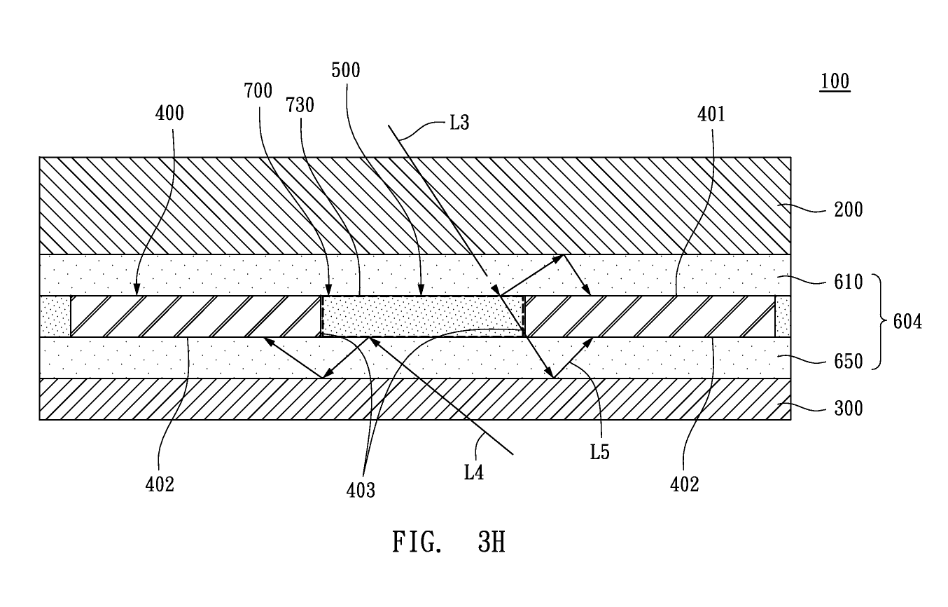

Reference is now made to FIG. 2 and FIG. 3A, in which FIG. 2 is a top view of a photovoltaic device 100 of the present disclosure, and FIG. 3A is a cross sectional view of FIG. 2 taken along A-A according to a first embodiment of the photovoltaic device 100 of the present disclosure.

As shown from a side view of the photovoltaic device 100 (FIG. 3A), the photovoltaic device 100 includes a superstrate 200, a package structure 600, a plurality of photovoltaic cells 400 and a substrate 300.

The superstrate 200 is light-transmissive, e.g., is a glass plate capable of being penetrated through by lights. The substrate 300 is arranged in parallel with the superstrate 200, for example, is a glass plate capable of being penetrated through by lights or an electrical insulated back sheet capable of blocking lights. The package structure 600 is sandwiched between the superstrate 200 and the substrate 300, and encapsulates the photovoltaic cells 400 therein. The photovoltaic cells 400 are disposed flat and arranged at intervals inside the package structure 600, and between the superstrate 200 and the substrate 300. In the embodiment, the photovoltaic cells 400 are arranged with an array arrangement in the package structure 600 (FIG. 3A), however, the scope of the present disclosure is not limited to the disclosed arrangement.

The photovoltaic device is not limited in types, such as e.g., thin film solar cell modules, single or poly silicon solar cell modules.

Each of the photovoltaic cells 400 is substantially shaped as a plate, and formed with a front surface 401, a rear surface 402 and four lateral surfaces 403. The front surface 401 and the rear surface 402 are defined at two opposite sides of the photovoltaic cell 400, and are oppositely defined on two main surfaces of the photovoltaic cell 400. The front surface 401 faces the sky for receiving sunlight so as to be defined as a sun-facing surface, and the lateral surfaces 403 mutually surround the front surface 401 and the rear surface 402, and are adjacently provided between the front surface 401 and the rear surface 402. It is noted that the lengths of the lateral surfaces 403 of the photovoltaic cell 400 are not limited to be same or not.

Since the photovoltaic cells 400 are arranged side by side at intervals, two lateral surfaces 403 of each two neighboring photovoltaic cells 400 are faced to each other, and a gap zone 500 is defined by the facing lateral surfaces 403 of each two neighboring photovoltaic cells 400.

The height 500h of the gap zone 500 is equal to a vertical distance from the front surface 401 of the photovoltaic cell 400 to the rear surface 402 of the photovoltaic cell 400, and the width 500w of the gap zone 500 is equal to a horizontal distance between the two lateral surfaces 403 of the two neighboring photovoltaic cells 400 facing to each other.

Moreover, a plurality of reflection portions 700 are provided in the package structure 600, and the reflection portions 700 are respectively located in the gap zones 500 for reflecting lights from the superstrate 200 back to the photovoltaic cells 400.

Thus, for example, when a light L3 penetrates through the superstrate 200 and arrives at one of the gap zones 500, the reflection portion 700 installed in the gap zone 500 will reflect the light L3, redirect the light L3 towards one of the front surfaces 401 of the photovoltaic cells 400. The light L3 can eventually arrive at the front surface 401 of the photovoltaic cell 400, thus, the photovoltaic cell 400 converts the light L3 into electric power.

It is noted that since a light-reflection rate of the reflection portion 700 is in a range of 90%-100%, and is greater than a light-reflection rate of the package structure 600. As such, the light L3 can be effectively reflected back to the area between the superstrate 200 and the photovoltaic cell 400 so as to increase the possibility that the light L3 is converted into electric power by the photovoltaic cell 400.

The followings are several examples illustrating the alternative details of the present disclosure according to the aforementioned descriptions.

Refer to FIG. 2 and FIG. 3A again. According to the first embodiment thereof, the package structure 600 further includes a first package layer 610 and a second package layer 620 with are stacked with each other. The first package layer 610 is light-transmissive, and entirely contacted with one surface of the superstrate 200. The first package layer 610, for example, is made of package material with super absorbent characteristics, such as ethylene/vinyl acetate copolymer (EVA), silicone rubber, or polyolefin-based copolymer (Polyolefin) etc.

The second package layer 620 is light-reflective, and one surface of the second package layer 620 is contacted to one surface of the first package layer opposite to the superstrate 200, and the other surface of the second package layer 620 is entirely contacted with one surface of the substrate 300. The second package layer 620, for example, is made of package material with high reflectance and low transmittance characteristics, such as ethylene/vinyl acetate copolymer (EVA), silicone rubber, or polyolefin-based copolymer (Polyolefin) etc.

In the first embodiment, the first package layer 610 is transparent or at least translucent (i.e. being light transmittable). The package material of the second package layer 620 is the material with brighter color (e.g., white or silver color etc.) so that comparing to the first package layer 610, the second package layer 620 can have higher light-reflective, high reflectance and low transmittance characteristics. The photovoltaic cells 400 are encapsulated and sandwiched between the first package layer 610 and the second package layer 620.

It is noted that both of the first package layer 610 and the second package layer 620 disposed in all gap zones 500 contact the lateral surfaces 403 of each two neighboring photovoltaic cells 400 facing to each other, that is, both of the first package layer 610 and the second package layer 620 seal all of the gap zones 500.

When being assembled, first, the first package layer 610 is entirely provided on a surface of the superstrate 200, and the second package layer 620 is entirely provided on a surface of the substrate 300; next, the photovoltaic cells 400 are placed flat between the first package layer 610 and the second package layer 620; finally, the superstrate 200 and the substrate 300 are laminated together so that the photovoltaic cells 400 are sandwiched and encapsulated between the first package layer 610 and the second package layer 620, and the joint surfaces of the first package layer 610 and the second package layer 620 are only located in all of the gap zones 500.

Thus, when the light L3 penetrates through the superstrate 200 and arrives at one of the gap zones 500, since the second package layer 620 is with high reflectance characteristics, a junction surface 621 (i.e. one alternative of the reflection portion 700) of the second package layer 620 contacting to the first package layer 610 in the gap zone 500 can reflect the light L3 towards one surface of the superstrate 200 facing the photovoltaic cells 400. After the light L3 is reflected by the superstrate 200, the light L3 eventually arrives at the front surface 401 of the photovoltaic cell 400. Thus, the photovoltaic cell 400 converts the light L3 into electric power.

In this embodiment, a light-reflection rate of the junction surface 621 is in a range of 90%-100%, and is greater than a light-reflection rate of the first package layer 610.

Furthermore, in other alternatives of the embodiment, the personnel also can modify the level of the junction surface 621 (i.e. one alternative of the reflection portion 700) of the second package layer 620 contacting to the first package layer 610 in the gap zone 500, so as to be coplanar with the front surface 401 of the photovoltaic cell 400, however, the present disclosure is not limited to what is mentioned above.

Reference is now made to FIG. 2 and FIG. 3B, in which FIG. 2 is a top view of a photovoltaic device 100 of the present disclosure, and FIG. 3B is a cross sectional view of FIG. 2 taken along A-A according to a second embodiment of the photovoltaic device 100 of the present disclosure.

According to the second embodiment thereof, the package structure 601 further includes a first package layer 610 and a second package layer 630 which are stacked with each other. The first package layer 610 is light-transmissive, and entirely contacted with one surface of the superstrate 200. The first package layer 610, for example, is made of package material with super absorbent characteristics, such as ethylene/vinyl acetate copolymer (EVA), silicone rubber, or polyolefin-based copolymer (Polyolefin) etc. In this embodiment, the first package layer 610 is transparent or at least translucent (i.e. light transmittable).

The second package layer 630 includes a plurality of first portions 631 and a plurality of second portions 632. Each of the first portions 631 has a top surface thereof with the same area as a bottom surface of one of the photovoltaic cells 400, and is sandwiched between one of the photovoltaic cell 400 and the substrate 300. The material of each of the first portions 631 can be adopted with the same penetration rate as the material of the first package layer 610, such as ethylene/vinyl acetate copolymer (EVA), silicone rubber, or polyolefin-based copolymer (Polyolefin) etc., or the material of each of the first portions 631 can be adopted with different penetration rate as the material of the first package layer 610, such as ethylene/vinyl acetate copolymer (EVA), silicone rubber, or polyolefin-based copolymer (Polyolefin) etc.

The second portions 632 are light-reflective, arranged at intervals with each other, and respectively disposed in the gap zones 500. One surface of each of the second portions 632 is contacted with the first package layer 610, and the other surface thereof is contacted with the substrate 300. The second package layer 620, for example, is made of package material with high reflectance and low transmittance characteristics, such as ethylene/vinyl acetate copolymer (EVA), silicone rubber, or polyolefin-based copolymer (Polyolefin) etc.

The package material of the second portions 632 is the material with brighter color (e.g., white or silver color etc.) so that comparing to the first package layer 610, the second package layer 620 can have higher light-reflective, high reflectance and low transmittance characteristics. The photovoltaic cells 400 are encapsulated and sandwiched between the first package layer 610 and the first portions 631, and the reflection portion is a junction surface 621 of one of the second portions 632 contacting to the first package layer 610 in the gap zone 500.

It is noted that both of the first package layer 610 and the second portions 632 disposed in all gap zones 500 contact the lateral surfaces 403 of each two neighboring photovoltaic cells 400 facing to each other, that is, both of the first package layer 610 and the second portions 632 seal all of the gap zones 500.

When being assembled, first, the first package layer 610 is entirely provided on a surface of the superstrate 200, and the second package layer 630 is entirely provided on a surface of the substrate 300; next, the photovoltaic cells 400 are placed flat between the first package layer 610 and the second package layer 630 in which the first portions 631 are respectively aligned with the photovoltaic cells 400, and the second portions 632 are respectively aligned with gap zones 500, finally, the superstrate 200 and the substrate 300 are laminated together so that the photovoltaic cells 400 are sandwiched and encapsulated between the first package layer 610 and the second package layer 630, at this time, each of the photovoltaic cells 400 is sandwiched between the first package layer 610 and one of the first portions 631, and the joint surfaces of the first package layer 610 and the second portions 632 are only located in all of the gap zones 500.

Thus, when the light L3 penetrates through the superstrate 200 and arrives at one of the gap zones 500, since the second portions 632 are with high reflectance characteristics, a junction surface 621 (i.e. one alternative of the reflection portion 700) of the second portion 632 contacting to the first package layer 610 in the gap zone 500 can reflect the light L3 towards one surface of the superstrate 200 facing the photovoltaic cells 400. After the light L3 is reflected by the superstrate 200, the light L3 eventually arrives at the front surface 401 of the photovoltaic cell 400. Thus, the light L3 can be used by the front surface 401 of the photovoltaic cell 400 for converting into electric power.

In this embodiment, a light-reflection rate of the junction surface 621 is in a range of 90%-100%, and is greater than a light-reflection rate of the first package layer 610.

Furthermore, in other alternatives of the embodiment, the personnel also can modify the level of the junction surface 621 (i.e. one alternative of the reflection portion 700) of the second portion 632 contacting to the first package layer 610 in the gap zone 500, so as to be coplanar with the front surface 401 of the photovoltaic cell 400, however, the present disclosure is not limited to what is mentioned above.

Reference is now made to FIG. 2 and FIG. 3C, in which FIG. 2 is a top view of a photovoltaic device 100 of the present disclosure, and FIG. 3C is a cross sectional view of FIG. 2 taken along A-A according to one alternative of a third embodiment of the photovoltaic device 100 of the present disclosure.

According to the third embodiment thereof, the package structure 602 further includes a first package layer 610 and a second package layer 640. The first package layer 610 is light-transmissive, and entirely contacted with one surface of the superstrate 200. The first package layer 610, for example, is made of package material with super absorbent characteristics, such as ethylene/vinyl acetate copolymer (EVA), silicone rubber, or polyolefin-based copolymer (Polyolefin) etc.

The second package layer 640 is light-transmissive, and entirely contacted with one surface of the substrate 300. The material of the second package layer 640 is same as the material of the first package layer 610. The photovoltaic cells 400 are encapsulated and sandwiched between the first package layer 610 and the second package layer 640.

The reflection portion 700 comprises a plurality of reflective films 710. The reflective films 710 are light-reflective, and arranged in the gap zones 500, respectively. Each of the reflective films 710 located in one of the gap zones 500 is connected with the lateral surfaces 403 of the neighboring photovoltaic cells 400. Each reflective film 710 contacts the lateral surfaces 403 of each two neighboring photovoltaic cells 400 facing to each other, that is, each reflective film 710 seals one of the gap zones 500.

Furthermore, since each reflective film 710 is sandwiched between the first package layer 610 and the second package layer 640, the first package layer 610 and the second package layer 640 are not physically contacted with each other.

In one alternative of the embodiment, the reflective film 710 is not fully filled in the gap zone 500, that is, the width 710D of the reflective film 710 is less than the height 500h of the gap zone 500.

In one alternative of this embodiment, the reflective film 710 for example, can be a painting layer, a coating layer or a foil layer etc., however, the present disclosure is not limited to the mentioned types of the reflective film 710.

In another alternative of this embodiment, the reflective film 710 for example, can be metal material such as aluminum, silver, nickel, titanium, or steel etc., however, the present disclosure is not limited to the mentioned types of the reflective film 710.

In another alternative of this embodiment, the color of the reflective film 710 for example, can be white or silver etc.; however, the present disclosure is not limited to the mentioned types of the reflective film 710.

Moreover, the thickness of the reflective film is in nano-class, and the nano-sized film is used to control destructive or constructive optical interferences. When the thickness of the reflective film is λ/2, the light-reflection rate is highest, however, the present disclosure is not limited to the mentioned description, the personnel also can modify the thickness and the light-reflection rate of the reflective film to adjust the transmission/reflectance of the reflective film according to requirements thereof.

Therefore, when the photovoltaic device 100 is a unifacial photovoltaic device, and when the light L3 penetrates through the superstrate 200 and arrives at one of the gap zones 500, since the reflective film 710 (i.e. one alternative of the reflection portion 700) in the gap zone 500 is with light-reflective characteristic, the reflective film 710 can reflect the light L3 towards one surface of the superstrate 200 facing the photovoltaic cells 400. After the light L3 is reflected by the superstrate 200, the light L3 eventually arrives at the front surface 401 of the photovoltaic cell 400. Thus, the light L3 can be used by the front surface 401 of the photovoltaic cell 400 for converting into electric power.

Oppositely, reference is now made to FIG. 3D, and FIG. 3D is a cross sectional view of FIG. 2 taken along A-A according to another alternative of the third embodiment of the photovoltaic device 100 of the present disclosure.

When the photovoltaic device 100 is a bifacial photovoltaic device, both of the superstrate 200 and substrate 300 are plates capable of being penetrated through by lights, and both of the front surface 401 and the rear surface 402 of the photovoltaic cells 400 are able to convert lights L3, L4 into electric power. Thus, when the light L4 penetrates through the substrate 300 and arrives at one of the gap zones 500, the reflective film 710 does not stop reflecting the light L4 towards one surface of the substrate 300 facing the photovoltaic cells 400 until the light L4 eventually arrives at the rear surface 402 of the photovoltaic cell 400. Thus, the light L4 can be used by the rear surface 402 of the photovoltaic cell 400 for converting into electric power.

If the light-reflection rate of the reflective film 710 is in a range of 50%-90%, the reflective film 710 is light-transflective. Thus, the light L3 can penetrate through the reflective film 710 via the first package layer 610, and after the light L3 arrives at the surface of the substrate 300 facing the photovoltaic cells 400, the light L3 can be reflected by the surface of the substrate 300 facing the photovoltaic cells 400, and a part L5 of the light L3 will be redirected towards the rear surface 402 of the photovoltaic cell 400. As a result, the part L5 of the light L3 can be used by the rear surface 402 of the photovoltaic cell 400 for converting into electric power.

Also, in other alternatives of the embodiment, the personnel also can modify the level of the reflective film 710 in the gap zone 500, so as to be coplanar with the front surface 401 of the photovoltaic cell 400; however, the present disclosure is not limited to what is mentioned above.

Reference is now made to FIG. 2 and FIG. 3E, in which FIG. 3E is a cross sectional view of FIG. 2 taken along A-A according to a alternative of a fourth embodiment of the photovoltaic device 100 of the present disclosure.

The package structure 603 comprises a first package layer 610. The first package layer 610 is light-transmissive, and sandwiched between the superstrate 200 and substrate 300.

Substantially, the first package layer 610, for example, is made of package material with super absorbent characteristics, such as ethylene/vinyl acetate copolymer (EVA), silicone rubber, or polyolefin-based copolymer (Polyolefin) etc. One surface of the first package layer 610 is entirely contacted with one surface of the superstrate 200, and the other surface of the first package layer 610 is entirely contacted with one surface of the substrate 300. The reflection portion 700 comprises a plurality of reflective particles 720. The photovoltaic cells 400 are encapsulated into the first package layer 610. The reflective particles 720 are light-reflective, and are distributed in the first package layer 610 corresponding to each of the gap zones 500.

In one alternative of this embodiment, the reflective particles 720 can be, for example, metal particles or optical brightener particles; however, the present disclosure is not limited to the mentioned type of the reflective particles 720.

In another alternative of this embodiment, the material of the reflective particles 720 for example, can be silver, gold, nickel, aluminum, tin, titanium, or the combination thereof; however, the present disclosure is not limited to the mentioned type of the reflective particles 720.

In the other alternative of this embodiment, the optical brightener particles for example, can be barium sulfate, titanium dioxide, silica or the composition thereof, however, the present disclosure is not limited to the mentioned type of the optical brightener particles.

In still another alternative of this embodiment, the color of the reflective particles 720 is, for example, white or silver; however, the present disclosure is not limited to the mentioned type of the colors.

Therefore, when the photovoltaic device 100 is a unifacial photovoltaic device, and when the light L3 penetrates through the superstrate 200 and arrives at one of the gap zones 500, since the reflective particles 720 (i.e. one alternative of the reflection portion 700) distributed in the gap zone 500 is with light-reflective characteristic, the reflective particles 720 can reflect the light L3 towards one surface of the superstrate 200 facing the photovoltaic cells 400. After the light L3 is reflected by the superstrate 200, the light L3 eventually arrives at the front surface 401 of the photovoltaic cell 400. Thus, the light L3 can be used by the front surface 401 of the photovoltaic cell 400 for converting into electric power.

On the other hand, FIG. 3F is a cross sectional view of FIG. 2 taken along A-A according to another alternative of the fourth embodiment of the photovoltaic device 100 of the present disclosure.

When the photovoltaic device 100 is a bifacial photovoltaic device, both of the superstrate 200 and substrate 300 are plates capable of being penetrated through by lights, and both of the front surface 401 and the rear surface 402 of the photovoltaic cells 400 are able to convert lights L3, L4 into electric power.

Thus, when the light L4 penetrates through the substrate 300 and arrives at one of the gap zones 500, the reflective particles 720 does not stop reflecting the light L4 towards one surface of the substrate 300 facing the photovoltaic cells 400 until the light L4 eventually arrives at the rear surface 402 of the photovoltaic cell 400. Thus, the light L4 can be used by the rear surface 402 of the photovoltaic cell 400 for converting into electric power.

If the light-reflection rate of the reflective portion 700 (e.g. reflective particles 720) is in a range of 50%-90%, the reflective portion 700 is light-transflective. Thus, the light L3 can penetrate through the reflective portion 700 (e.g. reflective particles 720) via the first package layer 610, and after the light L3 arrives at the surface of the substrate 300 facing the photovoltaic cells 400, the light L3 can be reflected by the surface of the substrate 300 facing the photovoltaic cells 400, and a part L5 of the light L3 will be redirected towards the rear surface 402 of the photovoltaic cell 400. Thus, the part L5 of the light L3 can be used by the rear surface 402 of the photovoltaic cell 400 for converting into electric power.

Also, in other alternatives of the embodiment, the personnel also can modify the level of the reflective film 710 in the gap zone 500, so as to be coplanar with the front surface 401 of the photovoltaic cell 400, however, the present disclosure is not limited to what is mentioned above.

Furthermore, in other alternatives of the embodiment, the personnel also can modify the position of the reflective particles 720 in the gap zone 500, so as to be coplanar with the front surface 401 of the photovoltaic cell 400, however, the present disclosure is not limited to what is mentioned above.

Reference is now made to FIG. 2 and FIG. 3G, in which FIG. 3G is a cross sectional view of FIG. 2 taken along A-A according to an alternative of a fifth embodiment of the photovoltaic device 100 of the present disclosure.

In this fifth embodiment, specifically, the package structure 604 includes a first package layer 610 and a second package layer 650 which are stacked with each other. The first package layer 610 is light-transmissive, and entirely contacted with one surface of the superstrate 200.

The first package layer 610, for example, is made of package material with super absorbent characteristics, such as ethylene/vinyl acetate copolymer (EVA), silicone rubber, or polyolefin-based copolymer (Polyolefin) etc.

The second package layer 650 is light-transmissive, and entirely contacted with one surface of the substrate 300. The material of the second package layer 650 is same as the material of the first package layer 610. The photovoltaic cells 400 are encapsulated and sandwiched between the first package layer 610 and the second package layer 650.

The reflection portion 700 comprises a plurality of filling layers 730. The filling layers 730 are light-reflective, and arranged in the gap zones 500, respectively. Each of the filling layers 730 located in one of the gap zones 500 is connected with the lateral surfaces 403 of the neighboring photovoltaic cells 400. Each filling layer 730 contacts the lateral surfaces 403 of each two neighboring photovoltaic cells 400 facing to each other, that is, each filling layer 730 seals one of the gap zones 500.

For example, in one alternative of the fifth embodiment, each of the filling layers 730 is completely filled in one of the gap zones 500, that is, the volume of one of the filling layers 730 is equal to that of one of the gap zones 500.

In another alternative of this fifth embodiment, the filling layer 730 is a white plastic; however, the present disclosure is not limited to that.

In one another alternative of this fifth embodiment, the filling layer 730 is not limited to package material or non-package material.

In still another alternative of this fifth embodiment, the thickness of the white plastic, for example, is in a range of 50-200 μm, and the material of the white plastic, for example, can be polyethylene terephthalate (PET) or Tedlar® PVF (˜50 μm).

Therefore, when the photovoltaic device 100 is a unifacial photovoltaic device, and when the light L3 penetrates through the superstrate 200 and arrives at one of the gap zones 500, since the filling layers 730 (i.e. one alternative of the reflection portion 700) is with light-reflective characteristic, the e filling layers 730 can reflect the light L3 towards one surface of the superstrate 200 facing the photovoltaic cells 400. After the light L3 is reflected by the superstrate 200, the light L3 eventually arrives at the front surface 401 of the photovoltaic cell 400. Thus, the light L3 can be used by the front surface 401 of the photovoltaic cell 400 for converting into electric power.

On the other hand, reference is now made to FIG. 2 and FIG. 3H in which FIG. 3H is a cross sectional view of FIG. 2 taken along A-A according to another alternative of the fifth embodiment of the photovoltaic device of the present disclosure.

When the photovoltaic device 100 is a bifacial photovoltaic device, both of the superstrate 200 and substrate 300 are plates capable of being penetrated through by lights, and both of the front surface 401 and the rear surface 402 of the photovoltaic cells 400 are able to convert lights L3, L4 into electric power.

Thus, when the light L4 penetrates through the substrate 300 and arrives at one of the gap zones 500, the filling layers 730 does not stop reflecting the light L4 towards one surface of the substrate 300 facing the photovoltaic cells 400 until the light L4 eventually arrives at the rear surface 402 of the photovoltaic cell 400. Therefore, the light L4 can be used by the rear surface 402 of the photovoltaic cell 400 for converting into electric power.

If the light-reflection rate of the reflective portion 700 (e.g. filling layers 730) is in a range of 50%-90%, the reflective portion 700 is light-transflective. Thus, the light L3 can penetrate through the reflective portion 700 (e.g. filling layers 730) via the first package layer 610, and after the light L3 arrives at the surface of the substrate 300 facing the photovoltaic cells 400, the light L3 can be reflected by the surface of the substrate 300 facing the photovoltaic cells 400, and a part L5 of the light L3 will be redirected towards the rear surface 402 of the photovoltaic cell 400. Thus, the part L5 of the light L3 can be used by the rear surface 402 of the photovoltaic cell 400 for converting into electric power.

Furthermore, in other alternatives of the embodiment, the personnel also can modify the level of filling layers 730 in the gap zone 500, so as to be coplanar with the front surface 401 of the photovoltaic cell 400, however, the present disclosure is not limited to what is mentioned above.

In the aforementioned embodiments, refer to FIG. 2, when the photovoltaic cells 400 are arranged with an array arrangement, each of the photovoltaic cells 400 adjacently disposed on the peripheral of the array is provided with one outer lateral surface 403A not facing to another photovoltaic cell 400, and a border zone 510 is defined between the outer lateral surfaces 403A and the package structure 600.

Thus, in the photovoltaic device 100, not only the aforementioned reflection portion 700 can be arranged in the gap zone 500 disposed between the lateral surfaces 403 of each two neighboring photovoltaic cells 400 facing to each other, but also the personnel can configures the aforementioned reflection portion 700 in the border zone 510 to couple to the corresponding outer lateral surface 403A according to requirements.

Furthermore, no matter a solder strip is existed between every two neighboring photovoltaic cells 400 facing to each other, the space between the two neighboring photovoltaic cells 400 is defined as the “gap zone”.

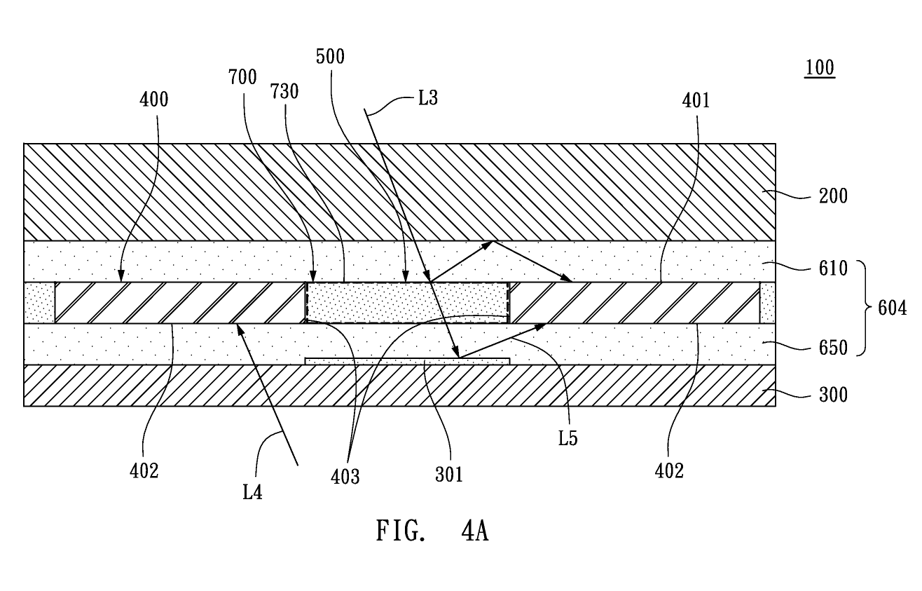

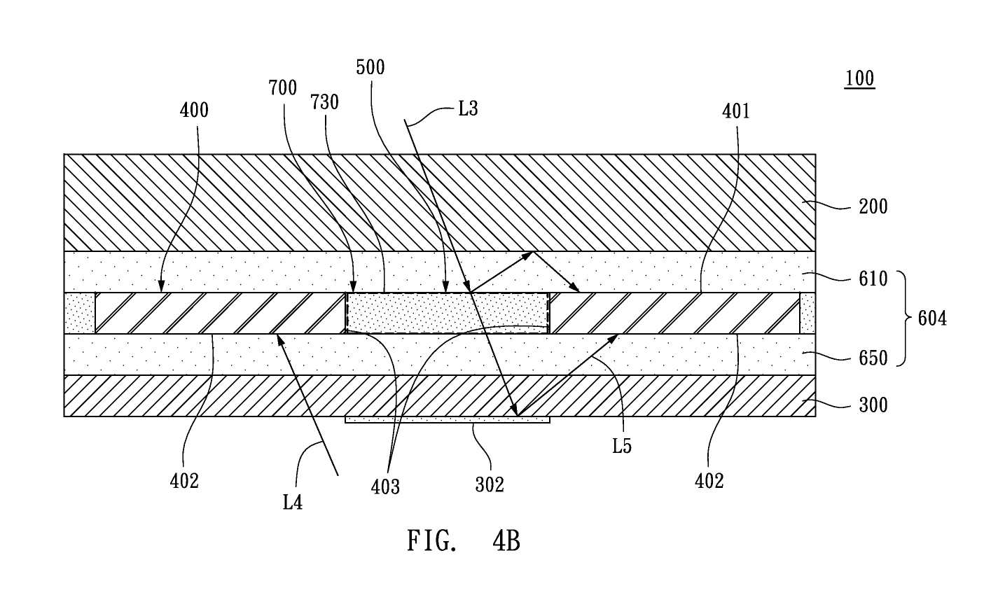

Reference is now made to FIG. 2 and FIG. 4A in which FIG. 4A is a cross sectional view of FIG. 2 taken along A-A according to an alternative of the sixth embodiment of the photovoltaic device 100 of the present disclosure.

This alternative of the sixth embodiment only is an option, and can be optionally adapted to the bifacial photovoltaic device of FIG. 3D, FIG. 3F or FIG. 3H, however, the present disclosure is not limited to what is mentioned above.

When the photovoltaic device 100 is a bifacial photovoltaic device, both of the superstrate 200 and substrate 300 are glass plates capable of being penetrated through by lights, and both of the front surface 401 and the rear surface 402 of the photovoltaic cells 400 are able to convert lights L3, L4 into electric power.

Refer to FIG. 3D, FIG. 3F or FIG. 3H, after the light L3 arrives the substrate 300, a part (e.g. lights L5) of the light L3 is reflected by the substrate 300 to the rear surface 402 of the photovoltaic cell 400, and the remain part of the light L3 will still be penetrated through the substrate 300. Thus, for a purpose of not wasting the remain part of the light L3 penetrated through the substrate 300, in this alternative of the sixth embodiment option, a reflective coating layer 301 (i.e. membrane) can be disposed on a surface (i.e. inner surface) of the substrate 300 facing to the photovoltaic cells 400 and corresponding to one of the gap zone 500. The required transmission/reflectance of the reflective coating layer 301 can be controlled by adjusting the thickness and refraction index of the reflective coating layer 301.

Thus, when the light L3 penetrates through the superstrate 200 and the filler layer 730, and arrives at one of the reflective coating layer 301, after the total reflection of the reflective coating layer 301, all of the light L3 (see light L5) are reflected back to the rear surface 402 of the photovoltaic cell 400 so as to further enhance the total conversion efficiency of the photovoltaic device 100.

Furthermore, a length of the reflective coating layer 301 is the same as the width 500w (see FIG. 3A) of the gap zone 500, in other words, the reflective coating layer 301 is disposed at a region that the gap zone 500 is vertically projected on the inner surface of the substrate 300, however, the present disclosure is not limited to what is mentioned above, such as the length of the reflective coating layer 301 also is not the same as the width 500w of the gap zone 500.

Moreover, in other alternatives of the embodiment, the personnel also can properly choose the light-reflection rate of the reflection portion 700 (e.g. the filler layer 730) so that the light-reflection rate of the reflection portion 700 (e.g. the filler layer 730) can be set low, moderate or high such as 10%, 50% or 90% so as to split the intensity of light L3, adjust the intensity of the light L3 penetrating through the reflection portion 700 (e.g. the filler layer 730) or the light L3 reflected from the reflection portion 700 (e.g. the filler layer 730).

Reference is now made to FIG. 2 and FIG. 4B, and FIG. 4B is a cross sectional view of FIG. 2 taken along A-A according to another alternative of the sixth embodiment of the photovoltaic device 100 of the present disclosure.

This alternative of the sixth embodiment can be optionally adapted to the bifacial photovoltaic device of FIG. 3D, FIG. 3F or FIG. 3H, however, the present disclosure is not limited to what is mentioned above.

When the photovoltaic device 100 is a bifacial photovoltaic device, both of the superstrate 200 and substrate 300 are glass plates capable of being penetrated through by lights, and both of the front surface 401 and the rear surface 402 of the photovoltaic cells 400 are able to convert lights L3, L4 into electric power.

Refer to FIG. 3D, FIG. 3F or FIG. 3H, after the light L3 arrives the substrate 300, a part (e.g. lights L5) of the light L3 is reflected by the substrate 300 to the rear surface 402 of the photovoltaic cell 400, and the remain part of the light L3 will still be penetrated through the substrate 300. Therefore, for a purpose of not wasting the remain part of the light L3 penetrated through the substrate 300, in this alternative of the sixth embodiment option, a reflective coating layer 302 (i.e. membrane) can be disposed on a surface (i.e. outer surface) of the substrate 300 opposite to the photovoltaic cells 400 and corresponding to one of the gap zone 500. The required transmission/reflectance of the reflective coating layer 302 can be controlled by adjusting the thickness and refraction index of the reflective coating layer 302.

Thus, when the light L3 penetrates through the superstrate 200 and the filler layer 730 and substrate 300, and arrives at one of the reflective coating layer 302, after the total reflection of the reflective coating layer 302, all of the light L3 (see light L5) are reflected back to the rear surface 402 of the photovoltaic cell 400 so as to further enhance the total conversion efficiency of the photovoltaic device 100.

Furthermore, a length of the reflective coating layer 302 is the same as the width 500w (see FIG. 3A) of the gap zone 500, in other words, the reflective coating layer 302 is disposed at a region that the gap zone 500 is vertically projected on the outer surface of the substrate 300, however, the present disclosure is not limited to what is mentioned above, such as the length of the reflective coating layer 302 also is not the same as the width 500w of the gap zone 500.

Moreover, in other alternatives of the embodiment, the personnel also can properly choose the light-reflection rate of the reflection portion 700 (e.g. the filler layer 730) so that the light-reflection rate of the reflection portion 700 (e.g. the filler layer 730) can be set low, moderate or high such as 10%, 50% or 90% so as to split the intensity of light L3, adjust the intensity of the light L3 penetrating through the reflection portion 700 (e.g. the filler layer 730) or the light L3 reflected from the reflection portion 700 (e.g. the filler layer 730).

To sum up, with the reflection portion installed in the photovoltaic device, the incident lights of the photovoltaic device can be reflected in advance by the reflection portion, such that the possibilities that the incident lights are invalided for converting into electric power can be decreased so as to further increase the total conversion efficiency of the photovoltaic device.

Although the present disclosure has been described with reference to the preferred embodiments thereof, it is apparent to those ordinarily skilled in the art that a variety of modifications and changes may be made without departing from the scope of the present disclosure which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A photovoltaic device, comprising:
a superstrate being light transmissive;
a substrate arranged in parallel with the superstrate;
a plurality of photovoltaic cells disposed side-by-side at intervals with each other between the superstrate and the substrate, wherein a gap zone is defined by two facing lateral surfaces of every two of the neighboring photovoltaic cells; and
a package structure sandwiched between the superstrate and the substrate, and encapsulating the photovoltaic cells between the superstrate and the substrate,
wherein a reflection portion is provided in the package structure, and the reflection portion is located in the gap zone for reflecting lights from the superstrate back to the photovoltaic cells.

2. The photovoltaic device according to claim 1, wherein the package structure comprises:
a first package layer being light-transmissive, and entirely contacted with one surface of the superstrate; and
a second package layer being light-reflective, and stacked on one surface of the first package layer opposite to the superstrate,
wherein the photovoltaic cells are sandwiched between the first package layer and the second package layer, and the reflection portion is a surface of the second package layer contacting to the first package layer in the gap zone.

3. The photovoltaic device according to claim 2, wherein a light-reflection rate of the reflection portion is in a range of 90% to 100%, and greater than a light-reflection rate of the first package layer.

4. The photovoltaic device according to claim 3, wherein the substrate is light-blocked or light-transmissive.

5. The photovoltaic device according to claim 1, wherein the package structure comprises:
a first package layer being light-transmissive, and entirely contacted with one surface of the superstrate; and
a second package layer comprising:
a plurality of first portions each having a top surface thereof with the same area as a bottom surface of one of the photovoltaic cells, and sandwiched between one of the photovoltaic cell and the substrate; and
a plurality of second portions being light-reflective, and respectively arranged in the gap zones, and one surface of each of the second portions contacted with the first package layer, and the other surface thereof contacted with the substrate,
wherein the photovoltaic cells are sandwiched between the first package layer and the first portions, and the reflection portion is a surface of one of the second portions in contact to the first package layer in the gap zone.

6. The photovoltaic device according to claim 5, wherein a light-reflection rate of the reflection portion is in a range of 90% to 100%, and greater than a light-reflection rate of the first package layer.

7. The photovoltaic device according to claim 6, wherein the substrate is light-blocked or light-transmissive.

8. The photovoltaic device according to claim 1, wherein the package structure comprises:
a first package layer being light-transmissive, and entirely contacted with one surface of the superstrate; and
a second package layer being light-transmissive, and entirely contacted with one surface of the substrate, wherein the photovoltaic cells are sandwiched between the first package layer and the second package layer; and
the reflection portion comprising:
a plurality of reflective films being light-reflective, and sandwiched between the first package layer and the second package layer, wherein each of the reflective films is located in one of the gap zones, and connected with the lateral surfaces of the neighboring photovoltaic cells.

9. The photovoltaic device according to claim 8, wherein a light-reflection rate of the reflection portion is in a range of 90% to 100%, and greater than a light-reflection rate of the first package layer.

10. The photovoltaic device according to claim 9, wherein the substrate is light-blocked or light-transmissive.

11. The photovoltaic device according to claim 8, wherein the substrate is light-transmissive, and the reflection portion is light-transflective, has a light-reflection rate in a range of 50% to 90%, and greater than a light-reflection rate of the first package layer.

12. The photovoltaic device according to claim 1, wherein the package structure comprises:
a first package layer being light-transmissive, and sandwiched between the superstrate and substrate; and
the reflection portion comprising:
a plurality of reflective particles being light-reflective, and distributed in the first package layer corresponding to the gap zones.

13. The photovoltaic device according to claim 12, wherein a light-reflection rate of the reflection portion is in a range of 90% to 100%, and greater than a light-reflection rate of the first package layer.

14. The photovoltaic device according to claim 13, wherein the substrate is light-blocked or light-transmissive.

15. The photovoltaic device according to claim 12, wherein the substrate is light-transmissive, and
the reflection portion is light-transflective, and has a light-reflection rate in a range of 50% to 90%, and greater than a light-reflection rate of the first package layer.

16. The photovoltaic device according to claim 1, wherein the package structure comprises:
a first package layer being light-transmissive, and entirely contacted with one surface of the superstrate; and
a second package layer being light-transmissive, and entirely contacted with one surface of the substrate, wherein the photovoltaic cells are sandwiched between the first package layer and the second package layer; and
the reflection portion comprising:
a plurality of filling layers being light-reflective, sandwiched between the first package layer and the second package layer, wherein each of the filling layers is located in one of the gap zones, and connected with the lateral surfaces of the neighboring photovoltaic cells.

17. The photovoltaic device according to claim 16, wherein a light-reflection rate of the reflection portion is in a range of 90% to 100%, and greater than a light-reflection rate of the first package layer.

18. The photovoltaic device according to claim 17, wherein the substrate is light-blocked or light-transmissive.

19. The photovoltaic device according to claim 16, wherein the substrate is light-transmissive, and
the reflection portion is with light-transflective property, has a light-reflection rate in a range of 50% to 90%, and greater than a light-reflection rate of the first package layer.

20. The photovoltaic device according to claim 16, wherein each of the filling layers is completely filled in one of the gap zones.

21. A photovoltaic device, comprising:
a superstrate being light-transmissive;
a substrate arranged in parallel with the superstrate;
a plurality of photovoltaic cells disposed flat and arranged at intervals between the superstrate and the substrate, wherein a gap zone is defined between two lateral surfaces of each two neighboring photovoltaic cells facing to each other; and
a package structure sandwiched between the superstrate and the substrate, and encapsulating the photovoltaic cells therein, wherein the package structure comprises:
a first package layer being light-transmissive, and entirely contacted with one surface of the superstrate; and
a reflection portion disposed in the gap zone for reflecting incident lights from the superstrate, wherein a light-reflection rate of the reflection portion is greater than a light-reflection rate of the first package layer.

22. The photovoltaic device according to claim 21, wherein the light-reflection rate of the reflection portion is in a range of 90% to 100%.

23. The photovoltaic device according to claim 22, wherein the substrate is light-blocked or light-transmissive.

24. The photovoltaic device according to claim 21, wherein the substrate is light-transmissive, and the light-reflection rate of the reflection portion is in a range of 90% to 100%.
